(19) United States
(12) Patent Application Publication
(10) Pub. No.: US 2017/0365486 A1
(43) Pub. Date: Dec. 21, 2017

(54) PATTERN PROCESSING METHOD, METHOD FOR MANUFACTURING SEMICONDUCTOR SUBSTRATE PRODUCT, AND PRETREATMENT LIQUID FOR PATTERN STRUCTURE

(71) Applicant: FUJIFILM Corporation, Tokyo (JP)

(72) Inventors: Keeyoung PARK, Haibara-gun (JP); Atsushi MIZUTANI, Haibara-gun (JP)

(73) Assignee: FUJIFILM Corporation, Tokyo (JP)

(21) Appl. No.: 15/643,942

(22) Filed: Jul. 7, 2017

Related U.S. Application Data
(63) Continuation of application No. PCT/JP2016/051736, filed on Jan. 21, 2016.

(30) Foreign Application Priority Data
Jan. 23, 2015 (JP) 2015-011646

(51) Int. Cl. H01L 21/306

(52) U.S. Cl. CPC H01L 21/30604

(57) ABSTRACT

Provided are a pattern processing method for applying a pretreatment liquid for modifying the surface of a pattern structure to a semiconductor substrate provided with the pattern structure, which has at least one of polysilicon, amorphous silicon, Ge, or a low dielectric constant material having a k value of 2.4 or less, a method for manufacturing a semiconductor substrate product, and a pretreatment liquid for a pattern structure.

### CROSS-REFERENCE TO RELATED APPLICATIONS

This application is a Continuation of PCT International Application No. PCT/JP2016/051736 filed on Jan. 21, 2016, which claims priority under 35 U.S.C. §119 (a) to Japanese Patent Application No. 2015-011646 filed on Jan. 23, 2015. Each of the above applications is hereby expressly incorporated by reference, in its entirety, into the present application.

### BACKGROUND OF THE INVENTION

### 1. Field of the Invention

The present invention relates to a pattern processing method, a method for manufacturing a semiconductor substrate product, and a pretreatment liquid for a pattern structure.

### 2. Description of the Related Art

In the manufacturing field through a fine pattern structure of a metal compound such as a semiconductor substrate or a micromachine, a technology for suppressing the collapse of the pattern structure thereof has been demanded. As miniaturization and high integration or an increase in speed of the semiconductor substrate product or the micromachine further advance, the pattern structure thereof becomes finer. Particularly, there is a problem in the collapse of pattern of the structure occurring due to an increase in the aspect ratio thereof. For example, when the pattern structure is formed by a columnar structure, a treatment liquid including water or a cleaning liquid may be applied to a fine separation portion. The treatment liquid or the cleaning liquid is evaporated at the time of drying, but the pattern is affected by surface tension during the process and is thus drawn to cause a collapse. Accordingly, this collapse becomes more remarkable as the pattern structure becomes finer.

It is required to design a pattern structure which does not cause such a pattern collapse, and the degree of freedom in designing is limited with the fine pattern formation. Alternatively, in order to suppress the collapse of a pattern structure, the application of a chemical liquid having a specific formulation to the surface of a pattern structure is proposed (refer to WO2011/049091A).

### SUMMARY OF THE INVENTION

The present invention is to provide a pattern processing method and a pretreatment liquid for a pattern structure which are particularly suitable for a pattern structure having at least one of polysilicon, amorphous silicon, Ge or a low dielectric constant material having a k value of 2.4 or less, can prevent the collapse of the pattern structure, and suppress or prevent damage caused by a chemical liquid.

The above problems can be solved by the following means.

[1] A pattern processing method comprising: applying a pretreatment liquid for modifying a surface of a pattern structure to a semiconductor substrate provided with the pattern structure, which has at least one of polysilicon, amorphous silicon, Ge, or a low-dielectric-constant material having a k value of 2.4 or less.

[2] The pattern processing method according to [1], in which the pattern processing is a treatment for suppressing a collapse of the pattern structure when the pattern structure is treated with another treatment liquid including water.

[3] The pattern processing method according to [1] or [2], in which the pattern structure is formed by a plurality of columnar structures erected through a separation portion.

[4] The pattern processing method according to [3], in which a separation width of the separation portion of the pattern structure is 1 nm or more and 100 nm or less.

[5] The pattern processing method according to [3] or [4], in which a member width of a columnar structure portion of the pattern structure is 1 nm or more and 50 nm or less.

[6] The pattern processing method according to any one of [1] to [5], in which the pattern structure having Ge is a pattern structure including SiGe as a material.

[7] The pattern processing method according to [6], in which static contact angles of both of a solid film of Si_{0.5}Ge_{0.5} and a solid film of Si_{0.15}Ge_{0.85} with respect to pure water when the pretreatment liquid is applied to the films are 80° or more and 95° or less.

[8] The pattern processing method according to any one of [1] to [7], in which the pretreatment liquid contains a fluorine compound.

[9] The pattern processing method according to [6], in which the pretreatment liquid contains a compound including a long chain alkyl group having 10 or more carbon atoms and having an ammonium group, a pyridinium group, an imidazolium group or a salt structure thereof.

[10] The pattern processing method according to [9], in which the compound including a long chain alkyl group having 10 or more carbon atoms and having an ammonium group or a salt structure thereof is a dialkyl dimethyl ammonium compound.

[11] The pattern processing method according to any one of [1] to [10], in which the pretreatment liquid contains 1% by mass or less of an organic solvent.

[12] The pattern processing method according to any one of [1] to [11], in which the pH of the pretreatment liquid is 7 or greater.

[13] The pattern processing method according to any one of [1] to [12], in which the pretreatment liquid contains an alkali component.

[14] The pattern processing method according to [13], in which the alkali component is an organic amine compound having a pKa of 8.5 to 10.5.

[15] The pattern processing method according to any one of [1] to [14], in which the pretreatment liquid is condensed in advance and diluted with water when used.

[16] The pattern processing method according to any one of [1] to [15], in which the pretreatment liquid is a kit used by mixing a first liquid and a second liquid.

[17] A method for manufacturing a semiconductor substrate product comprising: manufacturing a semiconductor substrate product through the pattern processing method according to any one of [1] to [16].

[18] The method for manufacturing a semiconductor substrate product according to [17], in which after the pattern processing, the pattern structure is treated with another treatment liquid including water.

[19] A pretreatment liquid that is a pretreatment liquid for modifying a surface of a pattern structure by applying the pretreatment liquid to a semiconductor substrate provided with the pattern structure having at least one of polysilicon, amorphous silicon, Ge or a low dielectric constant material having a k value of 2.4 or less, the pretreatment liquid being capable of suppressing collapse of the pattern structure when the pattern structure is treated with another treatment liquid including water.

[20] The pretreatment liquid according to [19] comprising: a fluorine compound.

[21] The pretreatment liquid for a pattern structure according to [19], in which the pretreatment liquid contains a compound including a long chain alkyl group having 10 or more carbon atoms and having an ammonium group, a pyridinium group, an imidazolium group, or a salt structure thereof.

[22] The pretreatment liquid for a pattern structure according to [21], in which the compound including a long chain alkyl group having 10 or more carbon atoms and having an ammonium group or a salt structure thereof is a dialkyl dimethyl ammonium compound.

[23] The pretreatment liquid for a pattern structure according to any one of [19] to [22], in which the pH is 7 or greater.

[24] The pretreatment liquid for a pattern structure according to any one of [19] to [23], further comprising: an alkali component.

The pattern processing method and the pretreatment liquid for a pattern structure of the present invention are particularly suitable for a pattern structure having at least one of polysilicon, amorphous silicon, Ge or a low dielectric constant material having a k value of 2.4 or less, the collapse of the pattern structure can be suppressed and damage caused by a chemical liquid can be suppressed and prevented.

The above-described and other characteristics and advantages of the present invention will be more clarified by the following descriptions with appropriate reference to the accompanying drawings.

### BRIEF DESCRIPTION OF THE DRAWINGS

FIGS. 1A to 1D are step explanatory views schematically showing a process of treating a pattern structure.

FIG. 2 is a cross-sectional view schematically showing an example in which the pattern structure is collapsed.

FIG. 3 is a schematic view explaining the meaning of each parameter applied to a capillary force calculation.

FIG. 4 is a side view schematically showing the contact angles of water measured in the examples.

### DESCRIPTION OF THE PREFERRED EMBODIMENTS

Below, preferable embodiments of the present invention will be described in detail with reference to the accompanying drawings.

Incidentally, the term “group (atom group)” used in the specification is intended to include both unsubstituted and substituted groups unless designated as “unsubstituted” or “substituted” within a range not impairing the effects of the present invention. For example, the term “alkyl group” used herein includes not only an alkyl group having no substituent (an unsubstituted alkyl group) but also an alkyl group having a substituent (a substituted alkyl group). The same will be applied to each compound.

In addition, in the specification, the term “(meth)acrylate” represents both or either of acrylate and methacrylate, “(meth)acryl” represents both or either of methacryl and acryl, and the term “(meth)acryloyl” represents both or either of acryloyl and methacryloyl.

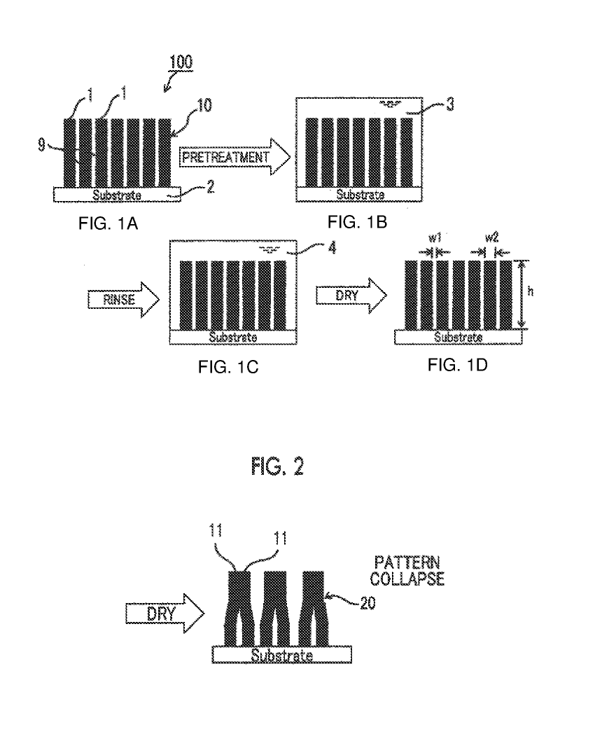

FIG. 1A to 1D are step explanatory views showing a process of a preferable embodiment of a processing method of the present invention. In FIGS. 1A to 1D, a flow of each step is shown. However, other appropriate steps may be provided before or after the steps or between the steps, or the order of procedure may be appropriately changed.

In FIG. 1A, a semiconductor substrate product (manufacturing intermediate) 100 in which a processed pattern structure 10 is provided on a substrate 2 is shown. The pattern structure 10 of the embodiment is shown in the form of a plurality of columnar structure portions 1, 1, 1 . . . , which are arranged through separation portions 9, 9, 9 . . . . In the embodiment, the columnar structure portion 1 has a rectangular shape in plan view and the entire columnar structure portion is formed like a wall. The drawing shows the cross-sectional view thereof (hatching is omitted). The wall-like columnar structure portions are arranged at equal intervals and form the pattern structure 10 of the embodiment. The method for forming such a structure is not particularly limited. As an example, an embodiment in which a resist (resin) is applied onto each columnar structure portion and the separation portions (intervals) are cut by dry etching using the resist as a mask to form the structure may be used. Thereafter, the remaining resist and residue can be removed by ashing or the like to obtain a desired columnar structure.

The member width w2 of the columnar structure portion 1 and the separation width w1 of the separation portion 9 are not particularly limited and the widths may be set to be appropriate according to the design of the element. In the embodiment, the sake of convenience of illustration, the width of the columnar structure portion 1 and the width of the separation portion are respectively equal and are set to have an equal interval.

In the specification, the pattern structure means a structure having unevenness on the surface according to a certain rule. Typically, a structure formed by a plurality of columnar structures erected through a predetermined separation portion may be exemplified. Here, the columnar structure is a general term for structures having a height and includes structures such as a wall-like structure in which structure portions are erected in a plane shape and a chevron structure as well as cylindrical and prismatic structures. From the viewpoint of more significantly exhibiting the effects of the present invention, the columnar structure is preferably a cylindrical structure, a prismatic structure, or a pattern structure in which a plurality of wall-like structures are arranged.

The member width w2 of the columnar structure portion is preferably 1 nm or more, more preferably 5 nm or more, and particularly preferably 10 nm or more. The upper limit is preferably 100 nm or less, more preferably 75 nm or less, and particularly preferably 50 nm or less.

The separation width w1 between each columnar structure portion is preferably 1 nm or more, more preferably 5 nm or more, and particularly preferably 10 nm or more. The upper limit is preferably 150 nm or less, more preferably 120 nm or less, and particularly preferably 100 nm or less.

The depth h of the pattern (the height of the columnar structure portion) is preferably 10 nm or more, more preferably 20 nm or more, and particularly preferably 30 nm or more. The upper limit is preferably 2,000 nm or less, more preferably 1,000 nm or less, and particularly preferably 100 nm or less.

The aspect ratio of the columnar structure portion (the value obtained by dividing the height by the member width) is preferably 1 or more, more preferably 10 or more, and particularly preferably 20 or more. The upper limit is preferably 100 or less, more preferably 50 or less, and particularly preferably 30 or less.

From the viewpoint of significantly exhibiting the effects of the present invention, it is preferable that the member width is small and the separation width is small. From the viewpoint of significantly exhibiting the effects of the present invention, it is preferable that the aspect ratio is high.

The positions for measuring the member width and the separation width may be set to be appropriate in consideration of the effects of the present invention, but typically, the member width and the separation width refer to widths measured at the central position of the height of the columnar structure portion. When the shape of the columnar structure portion and the separation portion is rectangular in plan view, the lengths of the short sides are respectively set to the widths. In the case of an undefined shape, ellipse or the like, the circle equivalent diameter may be set to the length (width).

FIG. 1B shows a step of treating the columnar structure 10 with a pretreatment liquid 3 which is a main part of the embodiment. The component composition of the pretreatment liquid and each physical property will be separately described in detail, but in the embodiment, it is preferable that the pretreatment liquid includes an alkali component and a fluorine compound. When the pretreatment liquid is applied to the structure and subsequently the pattern structure is treated with a treatment liquid including water (sometimes referred to as another treatment liquid or a rinsing liquid), it is possible to suppress or prevent the collapse of the pattern structure. Here, the term “collapse” should not be restrictively interpreted and means that the pattern structure is locally or entirely broken. Typically, the term “collapse” means that the structure is locally or entirely bent so that the columnar structure is destroyed.

FIG. 1C is a cross-sectional view schematically showing a rinsing step (post-treatment step). In the step, the pattern structure 10 is immersed in a bathtub filled with a rinsing liquid 4. Thus, the rinsing liquid can reach the wall surface of the columnar structure forming the pattern structure and the bottom portion of the separation portion. The rinsing liquid is not particularly limited but ultrapure water, which will be described later, is preferable. The rinsing step may be further carried out before a pretreatment step. That is, a plurality of rinsing steps may be carried out with a pretreatment step interposed therebetween.

FIG. 1D is a cross-sectional view schematically showing a drying step. Herein, the residues in the pattern structure 10 can be removed by evaporation using the rinsing liquid applied in advance. The drying step is preferably carried out by heating and the temperature of the environment atmosphere is preferably 15° or higher and 30° C. or lower. The drying atmosphere is not particularly limited, but for example, drying is carried out in N₂ gas. In the drying step, water is preferably removed from the separation portion by evaporating water remaining in the separation portion between the columnar structure portions.

FIG. 2 shows a step corresponding to FIG. 1D as a comparative example in which the above-described collapse occurs and is an example in which a post-treatment (rinsing step) is carried out without using the pretreatment liquid of the embodiment. Here, the columnar portions are collapsed so as to be drawn by the capillary force due to the application of an action by the surface tension of the liquid remaining in the separation portion in the evaporation process. As a result, an example in which the pattern structure 20 has collapsed and is destroyed such that the top portions of two adjacent columnar structure portions 11 and 11 are drawn to be brought into close contact with each other is shown. The form of the collapse in the case in which the pattern structure is collapsed by the surface tension of the rinsing liquid (the treatment liquid including water) is typically the form shown in the drawing.

Regarding the examples of the form and collapse of the pattern structure, JP2013-519217A and WO2011/049091A can be referred to.

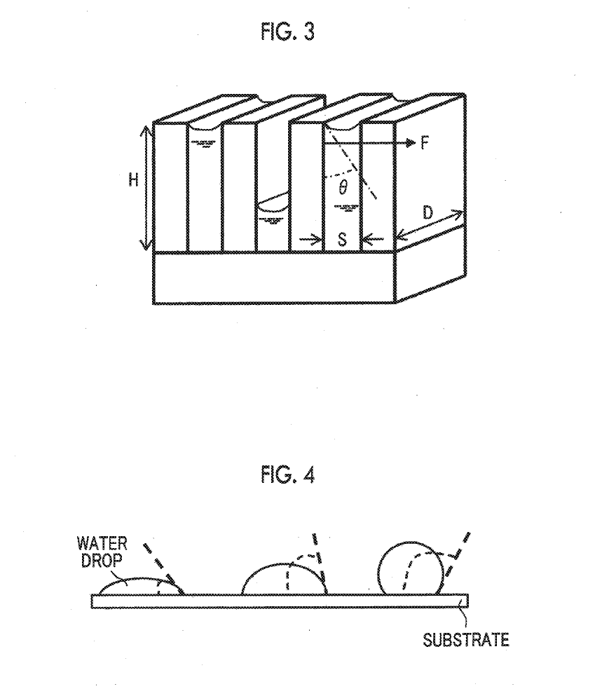

According to the findings of the present inventors, it has been found that the above-described effect of the rinsing liquid can be alleviated by lowering the surface tension of the liquid with respect to the pattern structure, and the collapse of the pattern structure can be suppressed or prevented. Accordingly, the collapse of the pattern structure can be prevented at the time of treatment with the rinsing liquid and at the time of drying of the rinsing liquid by reducing the surface tension of the liquid with respect to the pattern structure. According to the pretreatment liquid of the embodiment, the surface tension thereof can be reduced and thus the collapse of the pattern structure can be effectively suppressed. The surface tension can be calculated by the following Equation (I) by measuring the contact angle of the rinsing liquid (the treatment liquid including water). The meaning of each parameter can be understood by referring to FIG. 3.

F=2γD×(cos θ_{CA}+θₜ)×H/S (I)
F: capillary force
γ: surface tension
D: depth length of pattern
S: separation width w1 of pattern
θ_{CA}: contact angle of pattern structure surface
θₜ: taper angle of pattern
H: height of pattern

In the present invention, it is important to evaluate the ease of collapse (capillary force) by deriving the relational expression described above and measuring the surface contact angle of the pattern structure. By using the pretreatment liquid according to the preferable embodiment of the present invention, the contact angle of the rinsing liquid (the treatment liquid including water) is increased to reduce the capillary force so that a risk of the collapse of the pattern structure can be reduced.

<Pretreatment Liquid>

The pretreatment liquid according to the preferable embodiment of the present invention contains an alkali component and a fluorine compound. It is preferable that the pretreatment liquid further contains water.

(Alkali Component)

The alkali component is not particularly limited as long as the alkali component is a substance which makes the system of a water medium have alkalinity. The definition of alkali is required to be understood in a broadest sense and for example, alkali can be defined as a base using the definition of Arrhenius. An alkali compound may be an organic base or an inorganic base.

As the inorganic base, a compound represented by the following Formula (I-1) is exemplified.

M(OH)_{nI} (I-1)

M represents an alkali metal (preferably lithium, sodium, or potassium), an alkaline earth metal (preferably magnesium or calcium), NH₄, NR^{N}₂ (R^{N} represents a hydrogen atom or an alkyl group having 1 to 6 carbon atoms), a transition element (preferably manganese, zinc, or copper), or a rare earth metal (preferably lanthanum). nI represents an integer and an integer of 1 to 3 is preferable. In addition, nI is naturally determined by an element of M or an atomic group. When M represents H₄ or NR^{N}₂, nI is 1 and both cases are respectively compounds of ammonium hydroxide (NH₄OH) (noted as NH₃ in Examples below) and hydroxylamine (NH₂OH). nI is 1 in a case of an alkali metal and nI is 2 in a case of an alkaline earth metal. When M represents other transition elements or rare earth elements, nI may be suitably determined according to the valence of the corresponding element. As the inorganic base, hydrazine is further exemplified, and this is defined by the following Formula (H-1) of hydrazines.

Examples of the inorganic base include salts of alkali metals (for example, KOH, LiOH, and NaOH), salts of alkaline-earth metals (for example, Ca(OH)₂, and Mg(OH)₂), ammonium hydroxide salt, the hydrazines below, and hydroxylamine. Moreover, when M represents NR^{N}₂, nI is 1, but OH may be esterified and examples thereof include alkyl ester having 1 to 6 carbon atoms. In the case in which R^{N} represents a methyl group and methyl ester is formed, this becomes N,O-dimethylhydroxylamine.

Examples of the organic base include an organic amine compound and organic onium salt. As the organic amine compound, a compound represented by any of the following Formulae (O-1) to (O-3) is exemplified.

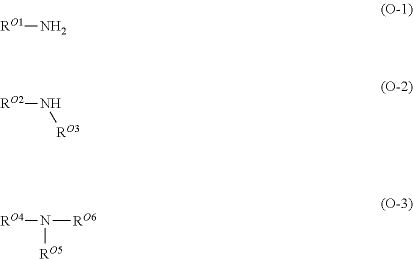

R⁰¹ to R⁰⁶ each independently represent an alkyl group having 1 to 20 carbon atoms (preferably having 1 to 8 carbon atoms and more preferably having 1 to 3 carbon atoms), an alkenyl group having 2 to 20 carbon atoms (preferably having 2 to 8 carbon atoms and more preferably having 2 or 3 carbon atoms), an alkynyl group having 2 to 20 carbon atoms (preferably having 2 to 8 carbon atoms and more preferably having 2 or 3 carbon atoms), an aryl group having 6 to 14 carbon atoms (preferably having 6 to 10 carbon atoms), an aralkyl group having 7 to 15 carbon atoms (preferably having 7 to 11 carbon atoms), or a group represented by the following Formula (y). R⁰¹ to R⁰⁶ may have an arbitrary substituent such as a hydroxyl group. Particularly, the alkyl group preferably constitutes an alkanolamine having a hydroxyl group. In addition, in this case, an oxygen atom or a sulfur atom, NR^{N} or the like may be interposed in the middle of the substituent (alkyl group or the like).

Examples of the organic base include aminoethanol (MEA: 2-Aminoethanol), diglycolamine (2-(2-aminoethoxy)ethanol) (DGA), benzylamine (BzA), N,N-dimethyl-2-aminoethanol (DMEA), and 2-methylaminoethanol (MAE).

Examples of the organic onium salt include a nitrogen-containing onium salt (quaternary ammonium salt or the like), a phosphorus-containing onium salt (quaternary phosphonium compound), and a sulfur-containing onium salt (for example, SRy3M: Ry represents an alkyl group having 1 to 6 carbon atoms and M represents a counter anion). Among these, a nitrogen-containing onium salt (a quaternary ammonium salt, a pyridinium salt, a pyrazolium salt, or an imidazolium salt) is preferable. As the alkali compound, among these, a quaternary ammonium hydroxide is preferable.

As the organic onium salt, a compound represented by the following Formula (O-4) or (O-5) is exemplified.

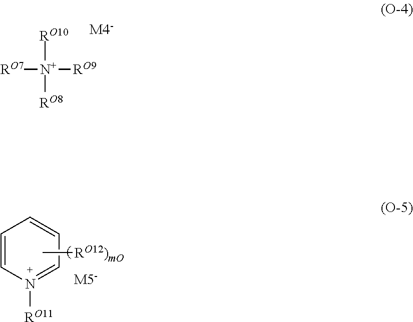

In Formula (O-4), R^{O7} to R^{O10} each independently represent an alkyl group having 1 to 20 carbon atoms (preferably having 1 to 8 carbon atoms and more preferably having 1 to 3 carbon atoms), an alkenyl group having 2 to 20 carbon atoms (preferably having 2 to 8 carbon atoms and more preferably having 2 or 3 carbon atoms), an alkynyl group having 2 to 20 carbon atoms (preferably having 2 to 8 carbon atoms and more preferably having 2 or 3 carbon atoms), an aryl group having 6 to 14 carbon atoms (preferably having 6 to 10 carbon atoms), an aralkyl group having 7 to 15 carbon atoms (preferably having 7 to 11 carbon atoms), or a group represented by the following Formula (y).

Y1-(Ry1-Y2)my-Ry2-* (y)

Y1 represents an alkyl group having 1 to 12 carbon atoms (preferably having 1 to 6 carbon atoms and more preferably having 1 to 3 carbon atoms), an alkenyl group having 2 to 12 carbon atoms (preferably having 2 to 6 carbon atoms and more preferably having 2 or 3 carbon atoms), an alkynyl group having 2 to 12 carbon atoms (preferably having 2 to 6 carbon atoms and more preferably having 2 or 3 carbon atoms), an aralkyl group having 7 to 15 carbon atoms (preferably having 7 to 11 carbon atoms), an aryl group having 6 to 14 carbon atoms (preferably having 6 to 10 carbon atoms), a hydroxyl group, or an alkoxy group having 1 to 4 carbon atoms (preferably having 1 to 6 carbon atoms). Y2 represents O, S, CO, or NR^{N} (R^{N} represents a hydrogen atom or an alkyl group having 1 to 6 carbon atoms). Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. my represents an integer of 0 to 6. When my represents an integer of 2 or greater, a plurality of Ry1's and Y2's may be different from each other. Ry1 and Ry2 may further have a substituent. The symbol “*” indicates a bond.

M4⁻ and M5⁻ represent a counterion such as a hydroxide ion.

In Formula (O-5), R^{O11} represents a group having the same definition as that for R^{O7}. R^{O12} represents an arbitrary substituent and is preferably the same as a substituent R^{N}. mO represents an integer of 0 to 5.

Specifically, tetraalkylammonium hydroxide (preferably having 4 to 25 carbon atoms) is preferable. At this time, the arbitrary substituent (for example, a hydroxyl group, an allyl group, or an aryl group) may be substituted with an alkyl group within a range not impairing the effects of the present invention. Further, the alkyl group may be linear, branched, or cyclic. Specific examples thereof include tetramethylammonium hydroxide (TMAH), tetraethylammonium hydroxide (TEAH), benzyl trimethyl ammonium hydroxide, ethyl trimethyl ammonium hydroxide, 2-hydroxyethyl trimethyl ammonium hydroxide, benzyl triethyl ammonium hydroxide, hexadecyl trimethyl ammonium hydroxide, tetrabutyl ammonium hydroxide (TBAH), tetrahexyl ammonium hydroxide (THAH), and tetrapropyl ammonium hydroxide (TPAH). Other examples thereof include benzalkonium chloride, benzethonium chloride, methylbezethonium chloride, cetylpyridinium chloride, cetrimonium, dofanium chloride, tetraethylammonium bromide, didecyl dimethyl ammonium chloride, and domiphen bromide.

It is preferable that the alkali compound include hydrazines represented by the following Formula (H-1).

R^{H1}₂N—NR^{H2}₂ (H-1)

R^{H1} and R^{H2} each independently represent a hydrogen atom, an alkyl group having 1 to 6 carbon atoms, an alkenyl group having 2 to 6 carbon atoms, an alkynyl group having 2 to 6 carbon atoms, an aryl group having 6 to 10 carbon atoms, or an aralkyl group having 7 to 15 carbon atoms. Specifically, hydrazine, phenyl hydrazine, methyl hydrazine, 1,2-dimethyl hydrazine, or 1,1-dimethyl hydrazine is preferable.

The above-described alkali component preferably is an organic amine compound having a pKa of 8.5 to 10.5. The term “pKa” is an index for quantitatively indicating the acid strength and is a synonym to acid dissociation constant. In consideration of a dissociative reaction in which hydrogen ions are released from an acid, an equilibrium constant Ka thereof is represented by a negative common logarithm pKa. As pKa becomes smaller, the acid becomes stronger. For example, a value calculated by using ACD/Labs (manufactured by Advanced Chemistry Development, Inc.) can be used.

The concentration of the alkali component in the pretreatment liquid is preferably 0.0001% by mass or more, more preferably 0.0005% by mass or more, and particularly preferably 0.001% by mass or more. The upper limit is preferably 1% by mass or less, more preferably 0.5% by mass or less, and particularly preferably 0.2% by mass or less. It is preferable that the concentration of the alkali component is set to be in the above-described range because in the subsequent treatment with the rinsing liquid, the contact angle of the rinsing liquid with respect to the pattern structure is increased so that the treatment can be suitably carried out and the collapse of the pattern structure can be effectively suppressed. One type of alkali component may be used or two or more types of alkali components may be used.

In the preferable embodiment of the present invention, it is preferable that the alkali component is applied and further used in combination with a fluorine compound and sterilization effect can be exhibited.

(Fluorine Compound)

The fluorine compound used in the present invention is preferably a perfluoro compound. The perfluoro compound is not particularly limited as long as the compound is a compound having a perfluoro group. The term “perfluoro group” means a group in which a predetermined substitutable portion in the compound is filled with a fluorine atom. Typically, a trifluoromethyl group or a pentafluorophenyl group may be exemplified. Thus, a trifluoromethyl.ethyl group (3,3,3-trifluoromethyl propyl group) and a methyl.difluoromethylene group (1,1-difluoroethyl group) are also included in the perfluoro group. Among these, the perfluoro group is preferably a perfluoroalkyl group (preferably having 1 to 12 carbon atoms, more preferably having 1 to 6 carbon atoms, and particularly preferably having 1 to 3 carbon atoms) or a perfluoroalkylene group (preferably having 2 to 12 carbon atoms and more preferably having 2 to 6 carbon atoms).

It is preferable that the perfluoro group is a group represented by the following Formula P1 or P2.

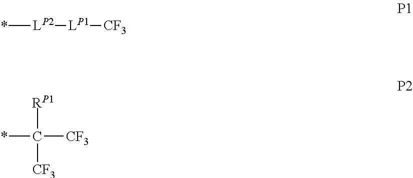

L^{P1} represents a single bond or an arbitrary linking group. Among linking groups, the linking group is preferably an alkylene group which may have a substituent (a halogen atom or the like) (preferably having 2 to 36 carbon atoms and more preferably having 2 to 18 carbon atoms) or a linking group having an oxygen atom (O) in the alkylene group. For L^{P1}, a halogen atom (fluorine atom) is preferably substituted.

L^{P2} represents a group having the same definition as that for Y2 or a single bond.

R^{P1} represents a hydrogen atom, an alkyl group (preferably having 1 to 12 carbon atoms, more preferably 1 to 6 carbon atoms, and particularly preferably 1 to 3 carbon atoms), or a halogen atom (fluorine atom), and a fluorine atom is preferable.

The symbol “*” indicates a bonding site. For the portion indicated by *, the group may be bonded to a substituent, a functional group, or a mother nucleus or may be introduced into the main chain or side chain of a polymer compound.

A perfluoro compound preferably has an ammonium group or a salt structure thereof, a pyridinium group or a salt structure thereof, or an imidazolium group or a salt structure thereof, in the molecule.

The perfluoro compound is preferably a perfluoro alkyl amine oxide, a perfluoroalkyl.alkylene oxide adduct, or a polymer surfactant having a polyethylene main chain. Among theses, a polymer having a poly(meth)acrylate structure is preferable. The poly(meth)acrylate is a general term for polyacrylate and polymethacrylate. Of these, in the present invention, a copolymer of the (meth)acrylate constituent unit having a polyoxy alkylene structure and a fluorinated alkyl acrylate constituent unit is preferable.

Alternatively, as the perfluoro compound, a compound having a perfluoroalkyl or perfluoroalkylene group (preferably having 1 to 24 carbon atoms and more preferably having 2 to 12 carbon atoms) in any site can be suitably used. Preferably, a polymer compound having the perfluoroalkyl or perfluoroalkylene group in the side chain can be used. As the perfluoro compound, a compound further having a polyoxyalkylene structure is preferable and a compound having a polyoxyalkylene structure in the side chain is more preferable. As the perfluoro compound, as an example thereof, a polymer having a repeating unit represented by the following Formula (F) is preferable.

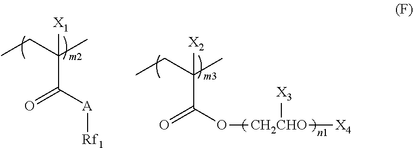

X₁ to X₄ each independently represent a hydrogen atom, an alkyl group, or a fluoroalkyl group.

A represents an oxygen atom, a sulfur atom, or —NR—. In the formula, R represents a hydrogen atom or an alkyl group.

The alkyl group for X₁, X₂, X₃, X₄ and R preferably has 1 to 12 carbon atoms, more preferably 1 to 6 carbon atoms, and particularly preferably 1 to 3 carbon atoms. Examples thereof include a methyl group, ethyl group, propyl group, i-propyl group, butyl group, i-butyl group, and t-butyl group.

m2 and m3 each independently represent an integer of 0 to 60.

n1 represents an integer of 0 to 20.

Rf₁ represents a fluoroalkyl group.

The fluoroalkyl group for X₁ to X₄ and Rf₁ preferably has 1 to 12 carbon atoms, more preferably 1 to 6 carbon atoms, and particularly preferably 1 to 3 carbon atoms. At this time, the alkyl chain may include 1 to 6 oxygen atoms (oxy group). For example, specific examples of the fluoroalkyl group include —CF₃, —C₂F₅, —C₄F₉, —CH₂CF₃, —CH₂C₂F₅, —CH₂C₃F₇, —CH₂C₄F₉, —CH₂C₆F₁₃, —C₂H₄CF₃, —C₂H₄C₂F₅, —C₂H₄C₄F₉, —C₂H₄C₆F₁₃, —C₂H₄C₈F₁₇, —CH₂CH(CH₃)CF₃, —CH₂CH(CF₃)₂, —CH₂CF(CF₃)₂, —CH₂CH(CF₃)₂, —CF₂CF(CF₃)OCF₃, —CF₂CF(CF₃)OC₃F₇, —C₂H₄OCF₂CF(CF₃)OCF₃, —C₂H₄OCF₂CF(CF₃)OC₃F₇, and —C(CF₃)═C(CF(CF₃)₂)₂.

Examples of the perfluoro compound include MEGAFAC F171, F172, F173, F176, F177, F141, F142, F143, F144, R30, F437, F479, F482, F552, F554, F558, F562, F780, and F781F (all manufactured by DIC Corporation), FLUORAD FC430, FC431, and FC171 (all manufactured by Sumitomo 3M Limited), SURFLON S-611, S-651, S-386, S-382, S-141, S-145, SC-101, SC-103, SC-104, SC-105, SC1068, SC-381, SC-383, 5393, KH-40, and S-221 (all manufactured by Asahi Glass Co., Ltd.), F-TOP EF301, EF303, EF351, and EF352 (all manufactured by Jemco Co., Ltd.), PF636, PF656, PF6320, PF6520, and PF7002 (manufactured by OMNOVA Co., Ltd.), FTERGENT 710FM and 300 manufactured by NEOS COMPANY LIMITED, and UV reactive surface modifier MEGAFAC RS series (MEGAFAC RS-75, MEGAFAC RS-72-K, MEGAFAC RS-76-E, MEGAFAC RS-76-NS, and MEGAFAC RS-90) manufactured by DIC Corporation.

The fluorine compound is, for example, a compound having a perfluoroalkyl group having 4 or more carbon atoms, preferably 6 or more carbon atoms, and still more preferably 8 or more carbon atoms. Although the upper limit is not particularly limited, the upper limit is substantially 36 or less. Further, it is preferable that the compound has a hydrophilic group and it is preferable that the hydrophilic group has a sulfonic acid group, a sulfonate group, a sulfonamide group, a hydroxyl group, and/or a carboxylic acid group.

For the fluorine compound, a fluorine-based surfactant can be used, a fluorine-based ionic surfactant is preferable, and a fluorine-based cationic surfactant is more preferable. The fluorine-based surfactant preferably has an ammonium group or a salt structure thereof, a pyridinium group or a salt structure thereof, or an imidazolium group or a salt structure thereof in the molecule.

For example, commercially available fluorine-based surfactants from each company can be suitably used as the fluorine-based surfactant. Examples of the fluorine-based surfactant include compounds in which a sulfonic acid group or a salt structure thereof, a carboxylic acid group or a salt structure thereof, a hydroxyl group, or the like are bonded to the bonding portion* in the above Formulae P1 and P2. An arbitrary linking group (for example, an alkylene group having a fluorine atom) may be included in the linked portion with the bonding portion *. Specific examples thereof include the followings.
Perfluoroalkyl sulfonic acid
   (CF₃(CF₂)ₙSO₃H: for example, n=7) [PFOS]
Perfluoroalkyl carboxylic acid
   (CF₃(CF₂)ₙCOOH: n=6) [PFOA]
Fluorinated telomer alcohol
   (F(CF₂)ₙCH₂CH₂OH)

Hereinafter, specific examples of a fluorine-based cationic surfactant that can be preferably used in the present invention will be exemplified but the present invention is not limited to these examples.

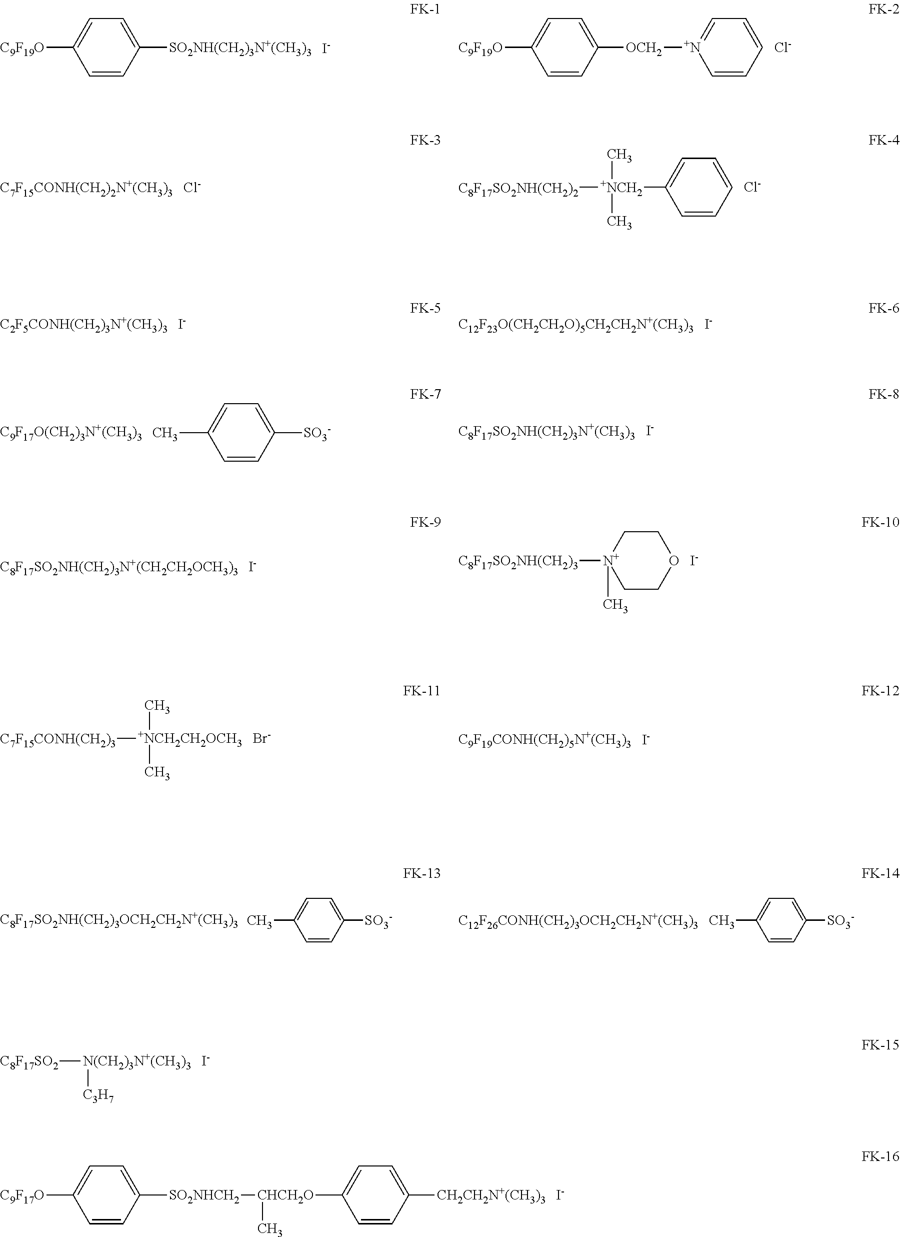

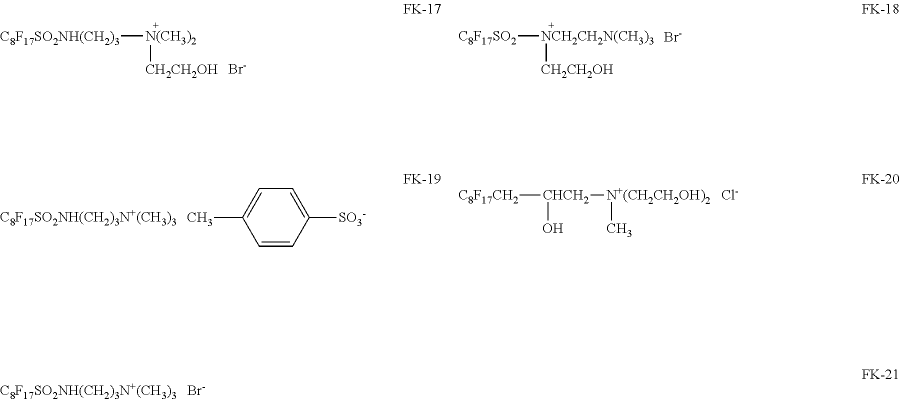

The fluorine compound preferably has a specific surface tension. Specifically, the surface tension is preferably 5 mN/m or more, more preferably 10 mN/m or more, and particularly preferably 15 mN/m or more. The upper limit is preferably 50 mN/m or less, more preferably 40 mN/m or less, and particularly preferably 30 mN/m or less.

With regard to a method for measuring the surface tension, measurement can be carried out by a suspended ring method, the Wilhelmy method, or the like. Examples of the measurement method include (A) a method using an automated surface tensiometer CBVP-Z (product name) manufactured by Kyowa Interface Science Co., Ltd. and (B) a method using a SIGMA 702 (product name) manufactured by KSV INSTRUMENTS LTD. In the specification, unless otherwise specified, a value measured by the above method (A) may be adopted. The temperature is set to a value measured at room temperature (23° C.) unless otherwise specified. The concentration is set to a value obtained by measuring a propylene glycol monomethyl ether (PGME) solution of 0.1% by mass of the perfluoro compound unless otherwise specified. In the case in which a compound is not dissolved in the solution, toluene may be used.

For the amount of the fluorine compound added, the fluorine compound is added within a range of preferably 10 parts by mass or more, more preferably 30 parts by mass or more, and particularly preferably 50 parts by mass or more with respect to 100 parts by mass of the alkali component as the lower limit. The upper limit is preferably 1,000 parts by mass or less, more preferably 500 parts by mass or less, and particularly preferably 300 parts by mass or less.

The content of the fluorine compound in the pretreatment liquid is preferably 0.0001% by mass or more, more preferably 0.0005% by mass or more, still more preferably 0.001% by mass or more, and even still more preferably 0.002% by mass or more. The upper limit is preferably 20% by mass or less, more preferably 10% by mass or less, still more preferably 5% by mass or less, and particularly preferably 1% by mass or less.

It is preferable that the content of the fluorine compound is within the above range since a desired contact angle of the rinsing liquid can be effectively exhibited.

The fluorine compound may be used alone or in combination of two or more thereof.

(Specific Compound Including Long Chain Alkyl Group)

In addition, it is preferable that the pretreatment liquid contains a compound including at least one and preferably two or more long chain alkyl groups having 10 or more carbon atoms (for example, a decyl group, a lauryl group, a myristyl group, a cetyl group, a stearyl, and a linoleyl group), and preferably a long chain alkyl group having 12 or more carbon atoms, and having an ammonium group, a pyridinium group, an imidazolium group, or a salt structure thereof. The above groups and the salt structures thereof are preferably included in the above-described fluorine compound.

The upper limit of the number of carbon atoms of the long chain alkyl group is not particularly limited, but is preferably 20 or less and more preferably 18 or less.

A compound including the long chain alkyl group and having an ammonium group or a salt structure thereof is preferably a compound represented by the following Formula (I).

N⁺(R¹)(R²)(R³)(R⁴)X⁻ Formula (I)

In Formula (I), R¹ represents the long chain alkyl group, and R² to R⁴ each independently represent the long chain alkyl group or an alkyl group having 1 to 9 carbon atoms. X⁻ represents a counterion.

An alkyl group having 1 to 9 carbon atoms for R² to R⁴ may be linear or branched. Examples thereof include methyl, ethyl, propyl, and t-butyl, and methyl is preferable.

X⁻ is preferably a halogen ion (for example, fluoride ion, chloride ion, bromide ion, or iodine ion), or a saccharin anion.

The alkyl chain of the long chain alkyl group or the alkyl group having 1 to 9 carbon atoms may have an arbitrary substituent or atom within a range not impairing the effects of the present invention. Examples of the substituent include —(CH₂CH₂)ₗOH (l is a positive integer).

The compound represented by the above Formula (I) is preferably a compound represented by the following Formula (II).

N⁺(R¹¹)(R¹²)(R¹³)(R¹⁴)Y⁻ Formula (II)

In Formula (II), R¹¹ and R¹² each independently represent the long chain alkyl group. R¹³ and R¹⁴ each independently represent an alkyl group having 1 to 9 carbon atoms. The alkyl group having 1 to 9 carbon atoms for R¹³ and R¹⁴ has the same meaning as the alkyl group having 1 to 9 carbon atoms for R² to R⁴ in Formula (I), and the preferable range thereof is also the same. Y⁻ has the same meaning as X⁻ in Formula (I) and the preferable range thereof is also the same.

Among the compound represented by Formula (II), R¹³ and R¹⁴ preferably represent methyl. That is, among the compounds represented by Formula (II), a dialkyl dimethyl ammonium compound is preferable.

The compound including the long chain alkyl group and having an ammonium group, a pyridinium group, an imidazolium group or a salt structure thereof can be appropriately synthesized by a common method. In addition, a compound available as a commercially available product can be used. Examples of the commercially available product include NEWKALGEN 500, and PIONIN B-651-P, B-811-S, B-231, B-111, B-8011, B-0011, B-2211, and B-251, manufactured by TAKEMOTO OIL & FAT CO., LTD., and AMIET302 manufactured by Kao Corporation (all of which are product names).

The compound including the long chain alkyl group and having an ammonium group, a pyridinium group, an imidazolium group, or a salt structure thereof may be used alone or in combination of two or more thereof.

In the present invention, the fluorine compound and the compound including the long chain alkyl group and having an ammonium group, a pyridinium group, an imidazolium group, or a salt structure thereof may be used in combination.

In addition, as long as the pretreatment liquid includes at least any one of the fluorine compound or the compound including the long chain alkyl group and having an ammonium group, a pyridinium group, an imidazolium group, or a salt structure thereof, the pretreatment liquid of the present invention may additionally include other surfactants.

Further, the compound including the long chain alkyl group and having an ammonium group, a pyridinium group, an imidazolium group, or a salt structure thereof is preferably a compound not having a fluorine atom.

The fluorine compound, such as surfactant, remaining on the substrate and other components may be removed by heating. Heating may be carried out in a vacuum or at normal pressure. The heating temperature is preferably 400° C. or lower.

(Water)

The pretreatment liquid of the present invention preferably contains water as a medium. The pretreatment liquid is preferably a water-based treatment containing water at a content of 50% or more. The water (water medium) may be an aqueous medium including a dissolved component within a range not impairing the effects of the present invention or may include a trace amount of unavoidable mixed components. Of these, distilled water, ion exchange water, or purified water such as ultrapure water is preferably used, and ultrapure water to be used in manufacturing a semiconductor is particularly preferably used.

The amount of water in the pretreatment liquid is preferably 70% by mass or more, more preferably 80% by mass or more, and still more preferably 90% by mass or more. In consideration of the addition of each component, the upper limit is preferably less than 100% by mass. It is preferable to set the amount of water to be within the above range since a suitable pretreatment effect can be obtained.

Other appropriate functional additives can be applied to the pretreatment liquid. For example, it is preferable to add organic solvents for dissolving each material and acids having a buffering action into the pretreatment liquid for obtaining a stable chemical liquid. Regarding these additives, in the case of using an organic solvent, the amount applied is preferably 1% by mass or less. Alternatively, anticorrosives (paragraph [0132] of JP2014-232874 A, paragraphs [0015] to [0022] of JP2014-185332A, and paragraphs [0030] to [0037] of JP2014-220300A), chelating agents (paragraph [0024] of JP2014-093407A, and paragraph [0024] of JP2014-041260A), and the like can be suitably used.

(Container)

The pretreatment liquid of the present invention (regardless of whether it is a kit or not) can be stored, transported and used by being poured into an arbitrary container, as far as corrosion and the like are not concerned. In addition, for semiconductor application, it is preferable that the container has high cleanliness and less elution of impurities therefrom. Examples of available containers include “CLEAN BOTTLE” series manufactured by AICELLO CORPORATION, and “PURE BOTTLE” manufactured by KODAMA PLASTICS Co., Ltd. However, the present invention is not limited to these. It is preferable that the container or the inner wall of the accommodation portion thereof is formed of a resin different from at least one resin selected from the group consisting of polyethylene resin, polypropylene resin, and polyethylene-polypropylene resin, or a metal which has been subjected to rust inhibition and metal elution preventing treatment.

As the different resin, a fluorine-based resin (perfluoro resin) can be particularly preferably used. In this manner, by using a container in which the inner wall of the accommodation portion is formed of a fluorine-based resin, as compared to the case of using a container in which the inner wall of the accommodation portion is formed of a polyethylene resin, polypropylene resin, or polyethylene-polypropylene resin, the occurrence of a defect in the elution of a oligomer of ethylene or propylene can be suppressed.

Specific examples of such a container in which the inner wall of the accommodation portion is formed of a fluorine-based resin include a FluoroPure PFA complex drum manufactured by Entegris Inc. In addition, containers described in page 4 of JP1991-502677A (JP-H03-502677A), page 3 of WO2004/016526A, pages 9 and 16 of WO99/46309A, and the like can be used.

<Filtering>

The pretreatment liquid of the present invention is preferably filtered with a filter for the purpose of removing foreign substances and reducing defects. The filter is not particularly limited as long as the filter is conventionally used for filtration or the like. For example, filters formed of fluororesins such as polytetrafluoroethylene (PTFE), polyamide resins such as nylon, polyolefin resins (including high density and ultra high molecular weight polyolefin resins) such as polyethylene, and polypropylene (PP) may be used. Among these materials, polypropylene (including high density polypropylene) and nylon are preferable. The pore diameter of the filter is suitably about 0.001 to 1.0 μm, preferably about 0.02 to 0.5 μm, and more preferably about 0.01 to 0.1 μm. When the pore diameter thereof is set to be within the range, fine foreign substances, such as impurities and aggregates, included in the pretreatment liquid can be reliably removed while suppressing filtration clogging.

When the filter is used, the filter may be combined with a different filter. At this time, the filtering with the first filter may be carried out only once or two or more times. In the case of carrying out filtering by combining the filter with a different filter two or more times, it is preferable that the pore diameter in the second filtering and subsequent filtering is equal to or larger than the pore diameter in the first filtering. In addition, within the above range, the filter may be combined with a first filter having a different pore diameter. Here, the pore diameter can be referred to the nominal values of filter makers. For example, a commercially available filter can be selected from various filters provided from Nihon Pall Ltd., Toyo Roshi Kaisha, Ltd., Nihon Entegris K.K. (previously Mykrolis Corporation), and Kits Microfilter Corporation.

The second filter can be formed by using the same material as the material of the above-described first filter. The pore diameter of the second filter is suitably about 0.01 to 1.0 μm and preferably about 0.1 to 0.5 μm. When the pore diameter thereof is set to be within the above range, in the case in which components particles are contained in the pretreatment liquid, foreign substances mixed in the pretreatment liquid can be removed while allowing the component particles to remain therein.

For example, the second filtering may be carried out after the filtering with the first filter has been carried out using a mixed liquid including some components of the pretreatment liquid and the remaining components are mixed with the filtrate to prepare a pretreatment liquid.

<Metal Concentration>

In the pretreatment liquid of the present invention, each concentration of each of metal ions (metal elements of Na, K, Ca, Fe, Cu, Mg, Mn, Li, Al, Cr, Ni, and Zn) included as impurities in the liquid is preferably 5 ppm or less (preferably 1 ppm). Particularly, since it is assumed that in the manufacturing of the most advanced semiconductor element, a pretreatment liquid having a higher purity is required, the metal concentrations thereof more preferably have values lower than the order of ppm, that is, in the order of ppb, and still more preferably have values in the order of ppt (all of the above concentrations are based on mass).

As the method for reducing the metal concentration, for example, a method in which at least one of the state of raw materials to be used when the pretreatment liquid is produced, or the stage after the pretreatment liquid has been prepared, distillation and filtration using an ion exchange resin is sufficiently carried out may be used.

As another method for the method of reducing the metal concentration, a method using, as a “container” for accommodating the raw materials to be used when the pretreatment liquid is produced, a container having less elution of impurities therefrom as shown in the description of the container for accommodating the pretreatment liquid may be used. In addition, a method of carrying out the lining of a fluorine-based resin on the inner wall of a pipe so that the metal component is not eluted from a “pipe” or the like at the time of preparation of the pretreatment liquid may be also used.

(Impurities.Coarse Particles)

It is preferable that the pretreatment liquid of the present invention includes a small amount of impurities, for example, metal powders, in the liquid in consideration of its usage. Particularly, the concentration of Na, K, and Ca ions in the liquid is preferably within a range of 1 ppt to 1 ppm (based on mass). In addition, in the pretreatment liquid, the number of coarse particles having an average particle diameter of 0.5 μm or more is preferably in a range of 100 particles/cm³ or less and more preferably in a range of 50 particles/cm³ or less.

(pH)

The pH of the pretreatment liquid in the preferable embodiment of the present invention is preferably 7 or greater, more preferably 8 or greater, and particularly preferably 9 or greater. The upper limit is preferably 14 or less, more preferably 13 or less, and particularly preferably 12 or less. The pH is a value measured at room temperature (25° C.) using F-51 (product name) manufactured by HORIBA Ltd.

(Static Contact Angle [θ_{CA}])

The static contact angle of the pretreatment liquid according to the preferable embodiment of the present invention is defined as the static contact angle of both the films with respect to pure water when a solid film of Si_{0.5}Ge_{0.5} and a solid film of Si_{0.15}Ge_{0.85} are treated. The specific static contact angle is preferably 50° or greater, more preferably 70° or greater, and particularly preferably 80° or greater. Although the upper limit is not particularly limited, the upper limit is preferably 110° or less, more preferably 100° or less, and particularly preferably 95° or less. The solid film of SiₓGe_{y} (x and y each independently represent a number of 0 or greater; however, x+y=1) generally refers to a flat film represented by a compositional formula of SiₓGe_{y} (a film which has not been subjected to pattern forming or the like).

<Treatment Method>

An embodiment of the pattern processing method of the present invention is not particularly limited. For example, a batch type treatment using a bath or a treatment using a single wafer type equipment may be adopted. Specifically, in a treatment using a bath, as shown in FIGS. 1A to 1D, a treatment can be carried out by immersing the pattern structure or a semiconductor substrate into a bath filled with the pretreatment liquid or the rinsing liquid. It is preferable that a single wafer type device has a treatment tank, in which the semiconductor substrate is transported or rotated in the treatment tank, and a peeling solution is applied (discharged, jetted, allowed to flow, added dropwise, or the like) into the treatment tank so that the peeling solution is brought into contact with the semiconductor substrate.

The treatment temperature of the pretreatment liquid and the rinsing liquid is preferably 10° C. or higher and more preferably 20° C. or higher. The upper limit is preferably 80° C. or lower, more preferably 60° C. or lower, and particularly preferably 40° C. or lower. The treatment temperature is based on the temperature to be applied to the substrate in the temperature measurement method shown in examples described later. The treatment temperature may be set to the storage temperature, the temperature in the tank in the case of management with a batch type treatment, or the temperature in the circulation flow path in the case of management in the circulation system.

<Material to be Treated>

As the material to be applied to the pattern processing method of the present invention, particularly, at least one of polysilicon, amorphous silicon, Ge, or a low dielectric constant material having a k value of 2.4 or less is adopted. Among these, at least one of Ge or a low dielectric constant material having a k value of 2.4 or less is preferably adopted, and Ge is more preferably adopted. The present invention has the above characteristics and exhibits specific effects (suppressing both the collapse and the damage of the pattern) exhibited by selecting these materials.

The material including Ge is not limited to a material constituting only Ge and may be, for example, a composite compound material of Ge and Si. Specific examples thereof include Si_{0.5}Ge_{0.5}, and Si_{0.15}Ge_{0.85}.

Examples of the low dielectric constant material having a k value of 2.4 or less include BDIII (Low-k) materials manufactured by Advanced Materials Technology. The k value can be measured by CMmap 92B (product name) manufactured by Four Dimensions, Inc (http://www.oyama-web.com/guide4/sub25.htm).

Each material of polysilicon, amorphous silicon, Ge, or a low dielectric constant material having a k value of 2.4 or less is separately treated in the manufacturing of the semiconductor substrate. Specifically, germanium (Ge) is used in a transistor portion of a semiconductor, and the low-k materials are used in a transistor portion, a BEOL portion, or the like.

<Kit and Concentrate>

The pretreatment liquid in the present invention may be used as a kit in which the raw materials are divided into multiple parts. For example, a liquid composition containing the fluorine compound in a water medium as a first liquid and a liquid composition containing the alkali component in a water medium as a second liquid are prepared. As the usage example thereof, it is preferable that a pretreatment liquid is prepared by mixing both the liquids and then the mixture is applied in the treatment on a timely basis. An organic solvent or the like may be further added to any of these liquids. In this manner, a desired action can be effectively exhibited without causing a deterioration in the liquid performance due to the decomposition of the fluorine compound. The concentration of the fluorine compound in the first liquid or the concentration of the alkali component in the second liquid can be set to be appropriate as a concentration after mixing based on the amount of formulation of the first liquid described above.

The pretreatment liquid of the present invention may be prepared in the form of a concentrate. In this case, the pretreatment liquid can be used by being diluted with water when being used.

In the specification, the expression “preparation” means to prepare a particular material by synthesis or blend and in addition, to include the procurement of prescribed materials by purchasing or the like. In addition, in the specification, to use a peeling solution so as to etch each material of the semiconductor substrate is called “application”. The embodiment thereof is not limited in particular. For example, this term is broad enough to include any embodiment of bringing an etching liquid and a semiconductor substrate into contact. Specifically, etching may be carried out by immersion using batch type equipment, or may be carried out by a discharge using single wafer type equipment.

The semiconductor substrate is used to refer to not only a silicon substrate (wafer) but also the entire substrate structure on which a circuit structure is formed. The semiconductor substrate member or the member refers to a member constituting the semiconductor substrate that is defined above and may be formed of a single material or a plurality of materials. The processed semiconductor substrate is sometimes called a semiconductor substrate product by distinction. A chip or a processed product thereof, which has been obtained by further processing the semiconductor substrate, if required, and then by singulating the same is referred to a semiconductor element or semiconductor device. That is, in the broad sense, the semiconductor element (semiconductor device) belongs to the semiconductor substrate product. Further, a product on which the above-described semiconductor element is mounted is referred to as a semiconductor product. The direction of the semiconductor substrate is not particularly limited. The columnar structure portion 1 side is called ns “upper”, while the substrate 2 side is called an “under” in the specification for the convenience of explanation. In the attached drawings, the structure of the semiconductor substrate or the member is shown in a simplified manner and may be interpreted as a necessary form if required.

### EXAMPLES

Next, the present invention will be described in detail with reference to examples, but the present invention is not limited to these examples. Note that the amount and ratio shown in the examples are based on mass, unless otherwise indicated.

### Example 1

A wafer in which films of each material shown in Table (solid films, that is, clean single films for an evaluation shown in the following <A> to <E>) was prepared. A treatment was carried out with 5% HF to remove the natural oxide film. The wafer after the pretreatment was used to conduct a beaker test. Specifically, while stirring the chemical liquid at room temperature at 250 rpm, the wafer was put into a beaker to carry out the pretreatment with each pretreatment liquid for 5 minutes. The wafer after the treatment was rinsed with flowing water (ultrapure water) for 5 seconds and dried with N₂ gas. The temperature at the time of drying was set to 20° C. (room temperature).

The contact angle of the wafer which had been subjected to a treatment with the pretreatment liquid was measured with the following contact angle device using water. This is an alternative measure of the above-described θ_{CA} and as this value increases, θ_{CA} decreases. As a result, it can be said that the capillary force in the pattern structure can be reduced.

The measurement of the static contact angle [θ_{AA}] was carried out using a DM-500 (product name) manufactured by Kyowa Interface Science Co., Ltd. at room temperature (25° C.) (refer to FIG. 4).

In addition, an Elipso meter was used to confirm the damage of each solid film. Specifically, the film thickness before and after the treatment was measured using an Elipso meter (Vase (product name), spectroscopic elipso meter, manufactured by J.A. Woollam Japan, was used) to calculate the thickness of the film to be removed. The average value at 5 points was adopted (measurement conductions: measurement range: 1.2 to 2.5 eV, measurement angle: 70, 75 degrees).

AA: Zero damage (no damage)

A: Damage of less than 1 Å/min

B: Damage of 1 Å/min or more and less than 5 Å/min

C: Damage of 5 Å/min or more and less than 10 Å/min

D: Damage of 10 Å/min or more

For measurement of bacteria, a commercially available measurement kit was used. Specifically, a bacteria detection medium “EASICULT COMBI” manufactured by COSMO BIO Co., Ltd. was used to confirm an increase in the number of bacteria after one week.

Good: A propagation of bacteria was not observed.

Bad: A propagation of bacteria was observed.

TABLE 1

| | Component composition | | | | | | | Temp. | Static contact angle [°] | |
|---|---|---|---|---|---|---|---|---|---|---|
| No | Component 1 | conc. (%) | Component 2 | conc. (%) | Component 3 | conc. (%) | pH | (° C.) | <A> | <B> |
| 101 | SurflonS221 | 0.05 | 25% | 0.025 | DI water | 99.925 | 11 | R.T. | 83.7 | 86.5 |
| | | | TMAH | | | | | | | |
| 102 | Ftergent 300 | 0.05 | 25% | 0.025 | DI water | 99.925 | 11 | R.T. | 81.3 | 90 |
| | | | TMAH | | | | | | | |
| 103 | NEWKALGEN | 0.05 | 25% | 0.025 | DI water | 99.925 | 11 | R.T. | 82.1 | 75.7 |
| | 500 | | TMAH | | | | | | | |
| 104 | PIONIN | 0.05 | 25% | 0.025 | DI water | 99.925 | 11 | R.T. | 83.1 | 79.8 |
| | B-651-P | | TMAH | | | | | | | |
| 105 | PIONIN | 0.05 | 25% | 0.025 | DI water | 99.925 | 11 | R.T. | 71.6 | 75.4 |
| | B-811-S | | TMAH | | | | | | | |
| 106 | PIONIN B-231 | 0.05 | 25% | 0.025 | DI water | 99.925 | 11 | R.T. | 77.2 | 79.6 |
| | | | TMAH | | | | | | | |
| 107 | PIONIN B-111 | 0.05 | 25% | 0.025 | DI water | 99.925 | 11 | R.T. | 78.3 | 78.6 |
| | | | TMAH | | | | | | | |
| 108 | Ftergent 300 | 0.09 | 25% | 0.026 | DI water | 99.884 | 11 | R.T. | 85.9 | 87.5 |
| | | | TMAH | | | | | | | |
| 109 | Ftergent 300 | 0.05 | 25% | 0.03 | DI water | 99.92 | 13 | R.T. | 78.7 | 80.2 |
| | | | TMAH | | | | | | | |
| 110 | Surflon S221 | 0.05 | 25% | 0.03 | DI water | 99.92 | 13 | R.T. | 80.2 | 81 |
| | | | TMAH | | | | | | | |
| 111 | PIONIN | 0.05 | 25% | 0.01 | DI water | 99.94 | 8 | R.T. | 72.5 | 73.8 |
| | B-651-P | | TMAH | | | | | | | |
| 112 | Surflon S221 | 0.05 | 25% | 0.01 | DI water | 99.94 | 8 | R.T. | 70.4 | 70.1 |
| | | | TMAH | | | | | | | |
| 113 | Ftergent 300 | 0.05 | MEA | 0.01 | DI water | 99.94 | 8 | R.T. | 79.5 | 76.4 |
| 114 | Ftergent 300 | 0.05 | DGA | 0.05 | DI water | 99.9 | 10 | R.T. | 84.5 | 74.1 |
| 115 | Surflon S221 | 0.05 | MEA | 0.05 | DI water | 99.9 | 11 | R.T. | 80.2 | 80.1 |
| 116 | Surflon S221 | 0.05 | DGA | 0.15 | DI water | 99.8 | 11 | R.T. | 80.4 | 76.5 |
| 117 | Ftergent 300 | 0.01 | DGA | 0.1 | DI water | 99.89 | 11 | R.T. | 79.2 | 80.1 |
| 118 | Ftergent 300 | 0.005 | DGA | 0.1 | DI water | 99.895 | 11 | R.T. | 75.4 | 82.4 |
| 119 | Surflon S221 | 0.01 | BzA | 0.05 | DI water | 99.94 | 10 | R.T. | 71.2 | 72.5 |
| 120 | Ftergent 300 | 0.01 | MAE | 0.11 | DI water | 99.88 | 11 | R.T. | 85.4 | 78.2 |
| 121 | PIONIN B-8811 | 0.01 | MEA | 0.11 | DI water | 99.88 | 11 | R.T. | 85.8 | 87.35 |
| 122 | PIONIN B-0011 | 0.01 | DGA | 0.1 | DI water | 99.89 | 11 | R.T. | 73.8 | 71.18 |
| 123 | PIONIN B-2211 | 0.03 | DGA | 0.05 | DI water | 99.92 | 10 | R.T. | 77.7 | 74.15 |
| 124 | PIONIN B-8811 | 0.004 | MEA | 0.1 | DI water | 99.896 | 11 | R.T. | 87.5 | 93.15 |
| 125 | PIONIN B-8811 | 0.0004 | TMAH | 0.025 | DI water | 99.9746 | 11 | R.T. | 81 | 82.68 |
| 126 | PIONIN B-251 | 0.005 | DGA | 0.11 | DI water | 99.885 | 11 | R.T. | 82.2 | 57.3 |
| 127 | AMIET 302 | 0.05 | TMAH | 0.025 | DI water | 99.925 | 11 | R.T. | 88.5 | 91.33 |

| | | | |
|---|---|---|---|
| C11 | Untreated: the contact angle of the untreated substrate was measured with pure water. | 60.9 | 54.06 |
| C12 | Untreated: the contact angle of the untreated substrate was measured with IPA | 0 | 0 |

| | Static contact angle [°] | | | Capillary force | | | | | | |
|---|---|---|---|---|---|---|---|---|---|---|
| No | <C> | <D> | <E> | <A> | <B> | <C> | <D> | <E> | Damage | Bacteria |
| 101 | 90.8 | 90.4 | 90.8 | 6365 | 3541 | −810 | −456 | −810 | AA | Good |
| 102 | 97.3 | 92.3 | 88.6 | 8773 | 0 | −7370 | −2404 | 1417 | AA | Good |
| 103 | 81 | 82.95 | 82.4 | 7972 | 14326 | 9073 | 7119 | 7671 | AA | Good |
| 104 | 83.2 | 84.9 | 79.3 | 6968 | 10271 | 6867 | 5080 | 10769 | AA | Good |
| 105 | 77.1 | 76.82 | 75.1 | 18308 | 14620 | 12949 | 13225 | 14914 | AA | Good |
| 106 | 80.2 | 83.6 | 83.7 | 12850 | 10470 | 9872 | 6465 | 6365 | AA | Good |
| 107 | 76.2 | 75.4 | 76.8 | 11762 | 11464 | 13835 | 14620 | 13244 | AA | Good |
| 108 | 91 | 97.3 | 94 | 4147 | 2530 | −1012 | −7370 | −4046 | AA | Good |
| 109 | 86.5 | 86.2 | 89.8 | 11365 | 9872 | 3541 | 3844 | 101 | C | Good |
| 110 | 83.2 | 85.8 | 88.5 | 9872 | 9073 | 6867 | 4248 | 1518 | B | Good |
| 111 | 69.6 | 70.1 | 82.4 | 17441 | 16181 | 20217 | 19742 | 7671 | AA | Bad |
| 112 | 55.3 | 52.6 | 70.1 | 19456 | 19742 | 33018 | 35228 | 19746 | AA | Bad |
| 113 | 68.8 | 72.5 | 85.4 | 10570 | 13638 | 20974 | 17441 | 4652 | AA | Good |
| 114 | 80.4 | 81.9 | 83.2 | 5559 | 15890 | 9673 | 8172 | 6867 | AA | Good |
| 115 | 75.4 | 86.1 | 80.4 | 9872 | 9972 | 14620 | 3945 | 9673 | AA | Good |
| 116 | 78.4 | 77.2 | 78.6 | 9673 | 13540 | 11663 | 12850 | 11464 | AA | Good |
| 117 | 82.2 | 83.4 | 80.5 | 10868 | 9972 | 7872 | 6666 | 9573 | AA | Good |
| 118 | 90.4 | 88.4 | 74.5 | 14620 | 7671 | −405 | 1619 | 15500 | AA | Good |
| 119 | 90.6 | 89.5 | 88.8 | 18691 | 17441 | −607 | 506 | 1215 | AA | Good |
| 120 | 78.2 | 82.5 | 84.2 | 4652 | 11861 | 11861 | 7571 | 5861 | AA | Good |
| 121 | 82.28 | 80.5 | 81.1 | 4248 | 2682 | 7796 | 9573 | 8973 | AA | Good |
| 122 | 63.33 | 65.5 | 72.5 | 16157 | 18715 | 26038 | 24052 | 17441 | AA | Good |
| 123 | 61.35 | 68.5 | 71.6 | 12380 | 15841 | 27809 | 21257 | 18308 | AA | Good |
| 124 | 83.53 | 80.4 | 81.5 | 2580 | −3187 | 6541 | 9673 | 8573 | AA | Good |
| 125 | 80.48 | 83.5 | 81.2 | 9123 | 7395 | 9598 | 6566 | 8873 | AA | Good |
| 126 | 47.3 | 65.5 | 60.5 | 7872 | 31334 | 39333 | 24052 | 28561 | AA | Good |
| 127 | 72.88 | 70.6 | 73.4 | 1544 | −1341 | 17079 | 19265 | 16570 | AA | Good |
| C11 | 26.12 | 25.32 | 73.1 | 28207 | 34042 | 52077 | 52428 | 16861 | D | Good |
| C12 | 0 | 0 | 0 | 16960 | 16960 | 16960 | 16960 | 16960 | D | Bad |

<Annotation of Table>
conc.: Concentration (% by mass)
R.T.: Room temperature (about 25° C.)
Surflon 5221 (product name), AGC semi chemical Co., Ltd.
Ftergent 300 (product name), NEOS Corporation
NEWKALGEN 500 (product name), TAKEMOTO OIL & FAT CO., LTD.
PIONIN B-651-P (product name), TAKEMOTO OIL & FAT CO., LTD. (cetylpyridinium chloride having a structure shown below)

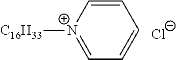

PIONIN B-811-S(product name), TAKEMOTO OIL & FAT CO., LTD. (stearyl trimethyl ammonium having a structure shown below)

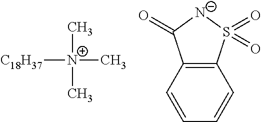

PIONIN B-231 (product name), TAKEMOTO OIL & FAT CO., LTD. (lauryl dimethyl benzyl ammonium chloride having a structure shown below)

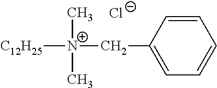

PIONIN B-111 (product name), TAKEMOTO OIL & FAT CO., LTD. (lauryl trimethyl ammonium chloride having a structure shown below)

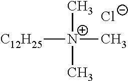

PIONIN B-8811 (product name), TAKEMOTO OIL & FAT CO., LTD. (distearyl dimethyl ammonium chloride having a structure shown below)

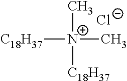

PIONIN B-0011 (product name), TAKEMOTO OIL & FAT CO., LTD. (didecyl dimethyl ammonium chloride having a structure shown below)

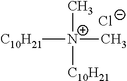

PIONIN B-2211 (product name), TAKEMOTO OIL & FAT CO., LTD. (dilauryl dimethyl ammonium chloride having a structure shown below)

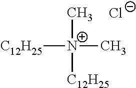

PIONIN B-251 (product name), TAKEMOTO OIL & FAT CO., LTD. (lauryl pyridinium chloride having a structure shown below)

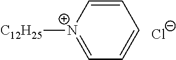

AMIET 302 (product name), Kao Corporation (polyoxyethylene alkylamine (the number of carbon atoms of alkyl is 18))
<A> Poly-Si S.E.H AMERICA.
<B> Si_{0.5}Ge_{0.5} Advanced materials technology Si/SiGe
<C> Si_{0.15}Ge_{0.85} Advanced materials technology Si/SiGe
<D> Ge KST world corp. Si/Ge
<E> BDIII(Low-k) Advanced materials technology Bare Si/BDIII of a k value up to 2.2

TMAH: tetramethylammonium hydroxide
MEA: 2-Aminoethanol
DGA: Diglycolamine
BzA: Benzylamine
DMEA: N,N-Dimetyl-2-aminoethanol
MAE: 2-(Methylamino)ethanol
DIwater: distilled water

The premises for the calculation of the capillary force in the table are as follows.
γ: 72.5 mN/m
D: 20 nm
S: 20 nm
θ_{CA}: measured value (°)
θₜ: 0°
H: 400 nm

As described above, it has been found that the pattern processing method and the pretreatment liquid of the pattern structure of the present invention are particularly suitable for a pattern structure having a specific material and capable of suppressing the collapse of the pattern structure by suppressing the surface tension thereof and suppressing or preventing damage due to a chemical liquid. Further, it has also been found that the propagation of bacteria in the treatment liquid can be effectively suppressed.

Although the present invention has been described in conjunction with the embodiments thereof, we do not intend to limit ourselves to any details in the descriptions of our invention unless otherwise specified and the invention should be widely interpreted without departing from the gist and scope of the invention shown in the appended claims.

### EXPLANATION OF REFERENCES

1 columnar structure portion
2: substrate
3: pretreatment liquid
4: rinsing liquid
9: separation portion
10: pattern structure
11: columnar structure portion (Comparative Example)
20: pattern structure (Comparative Example)
100: semiconductor substrate product

What is claimed is:

1. A pattern processing method comprising:
applying a pretreatment liquid for modifying a surface of a pattern structure to a semiconductor substrate provided with the pattern structure which has at least one of polysilicon, amorphous silicon, Ge, or a low-dielectric-constant material having a k value of 2.4 or less.

2. The pattern processing method according to claim 1,
wherein the pattern processing is a treatment for suppressing collapse of the pattern structure when the pattern structure is treated with another treatment liquid including water.

3. The pattern processing method according to claim 1,
wherein the pattern structure has a plurality of columnar structures erected through a separation portion.

4. The pattern processing method according to claim 3,
wherein a separation width of the separation portion of the pattern structure is 1 nm or more and 100 nm or less.

5. The pattern processing method according to claim 3,
wherein a member width of a columnar structure portion of the pattern structure is 1 nm or more and 50 nm or less.

6. The pattern processing method according to claim 1,
wherein the pattern structure having Ge is a pattern structure including SiGe as a material.

7. The pattern processing method according to claim 6,
wherein static contact angles of both of a solid film of Si_{0.5}Ge_{0.5} and a solid film of Si_{0.5}Ge_{0.5} with respect to pure water when the pretreatment liquid is applied to the films are 80° or more and 95° or less.

8. The pattern processing method according to claim 1,
wherein the pretreatment liquid contains a fluorine compound.

9. The pattern processing method according to claim 1,
wherein the pretreatment liquid contains a compound including a long chain alkyl group having 10 or more carbon atoms and having an ammonium group, a pyridinium group, an imidazolium group or a salt structure thereof.

10. The pattern processing method according to claim 9,
wherein the compound including a long chain alkyl group having 10 or more carbon atoms and having an ammonium group or a salt structure thereof is a dialkyl dimethyl ammonium compound.

11. The pattern processing method according to claim 1,
wherein the pretreatment liquid contains 1% by mass or less of an organic solvent.

12. The pattern processing method according to claim 1,
wherein the pH of the pretreatment liquid is 7 or greater.

13. The pattern processing method according to claim 1,
wherein the pretreatment liquid contains an alkali component.

14. The pattern processing method according to claim 13,
wherein the alkali component is an organic amine compound having a pKa of 8.5 to 10.5.

15. The pattern processing method according to claim 1,
wherein the pretreatment liquid is condensed in advance and diluted with water when being used.

16. The pattern processing method according to claim 1,
wherein the pretreatment liquid is a kit used by mixing a first liquid and a second liquid.

17. A method for manufacturing a semiconductor substrate product comprising:
manufacturing a semiconductor substrate product through the pattern processing method according to claim 1.

18. The method for manufacturing a semiconductor substrate product according to claim 17,
wherein after the pattern processing, the pattern structure is treated with another treatment liquid including water.

19. A pretreatment liquid for modifying a surface of a pattern structure by applying the pretreatment liquid to a semiconductor substrate provided with the pattern structure having at least one of polysilicon, amorphous silicon, Ge or a low dielectric constant material having a k value of 2.4 or less, the pretreatment liquid being capable of suppressing collapse of the pattern structure when the pattern structure is treated with another treatment liquid including water.

20. The pretreatment liquid according to claim 19, comprising:
a fluorine compound.

21. The pretreatment liquid for a pattern structure according to claim 19,
wherein the pretreatment liquid contains a compound including a long chain alkyl group having 10 or more carbon atoms and having an ammonium group, a pyridinium group, an imidazolium group, or a salt structure thereof.

22. The pretreatment liquid for a pattern structure according to claim 21,
wherein the compound including a long chain alkyl group having 10 or more carbon atoms and having an ammonium group or a salt structure thereof is a dialkyl dimethyl ammonium compound.

23. The pretreatment liquid for a pattern structure according to claim 19,
wherein the pH is 7 or greater.

24. The pretreatment liquid for a pattern structure according to claim 19, further comprising:
an alkali component.
